(19) United States
(12) Patent Application Publication
(10) Pub. No.: US 2016/0352297 A1
(43) Pub. Date: Dec. 1, 2016

(54) SYSTEM FOR AUTOMATIC ADJUSTMENT OF AUDIO VOLUME DURING OCCUPANT COMMUNICATION AND PROCESS THEREOF

(71) Applicant: Toyota Motor Engineering & Manufacturing North America, Inc., Erlanger, KY (US)

(72) Inventors: Jeffrey Edward Pierfelice, Canton, MI (US); Eric Randell Schmidt, Northville, MI (US)

(21) Appl. No.: 14/721,322

(22) Filed: May 26, 2015

(51) Int. Cl. H03G 3/20

(52) U.S. Cl. CPC H03G 3/20

(57) ABSTRACT

An audio volume control system that automatically reduces a volume the audio system when a person is speaking. The system includes an audio system with an acoustic speaker that is operable to detect sound waves in the interior space and transmit sound wave signals corresponding to the detected sound waves. An electronic control unit (ECU) is part of the audio volume control system and is in communication with the audio system and the microphone. The ECU is configured to instruct the audio system to reduce a volume of sound being transmitted into the interior space when an individual is detected to be speaking within the interior space.

### FIELD OF THE INVENTION

The present invention is directed to an audio volume control system and in particular to an audio volume control system for automatically adjusting audio volume during occupant communication within an interior space.

### BACKGROUND OF THE INVENTION

The use of an audio system that includes a radio, CD player, and the like during operation of a motor vehicle is known. In addition, it is known that when an individual within the interior of a motor vehicle desires to speak to another individual within the vehicle or talk on a cell phone while the audio system is in operation, the volume of the audio system can need to be reduced or “turned down.” Heretofore known systems require that an individual manually reduce such a volume, which can in turn require the individual to use one of their hands to physically do so. As such, a system and process that affords for a volume of an audio system that is transmitting sound within an interior space to be automatically reduced when an individual within the interior space communicates or speaks would be desirable.

### SUMMARY OF THE INVENTION

An audio volume control system is provided. The system includes an interior space within a physical boundary and an audio system with an acoustic speaker. The audio system with the acoustic speaker is operable to transmit sound in the form of music, news, talk radio, etc., into the interior space. A microphone is also included and is operable to detect sound waves in the interior space and transmit sound wave signals corresponding to the detected sound waves. An electronic control unit (ECU) is part of the audio volume control system and is in communication with the audio system and the microphone. The ECU is configured to instruct the audio system to reduce a volume of sound being transmitted into the interior space when an individual is detected speaking within the interior space.

In some instances, a voice recognition system (VRS) is included and is operable to recognize a voice of the individual and transmit a voice-recognized signal to the ECU when the voice of the individual is recognized. The ECU can then instruct the audio system to reduce the volume of sound being transmitted into the interior space when the voice-recognized signal is received from the VRS.

An occupant detection system (ODS) can optionally be included and be operable to detect when an occupant is in the interior space and transmit an occupant-detected signal to the ECU when the occupant is detected. In such instances, the ECU can be configured to instruct the audio system to reduce the volume of sound being transmitted into the interior space when the voice-recognized signal is received from the VRS and the occupant-detected signal is received from the ODS. The ODS can be selected from at least one of a camera ODS, an ultrasound ODS, and a weight sensor ODS.

In other instances, the ECU is configured to receive acoustic signals directly from the audio system, the acoustic signals corresponding to the sound transmitted into the interior space. The ECU is also configured to subtract the received acoustic signals from sound wave signals received from the microphone. In such instances, the ECU is configured to instruct the audio system to reduce the volume of sound being transmitted into the interior space after the acoustic signals received directly from the audio system are subtracted from the sound wave signals received from the microphone and the individual is detected to be speaking within the interior space. Such a system can also include the ODS which is operable to detect when an occupant is in the interior space and transmit an occupant-detected signal to the ECU. Also, the ECU can be configured to instruct the audio system to reduce the volume of sound being transmitted into the interior space after the acoustic signals received directly from the audio system are subtracted from the sound wave signals received from the microphone and the occupant-detected signal is received from the ODS.

A process for reducing the volume of an audio system when an individual is speaking includes providing an audio volume control system and the system detecting the individual is speaking within an interior space. Thereafter, the ECU instructs the audio system to reduce a volume of sound being transmitted into the interior space.

### BRIEF DESCRIPTION OF THE DRAWINGS

FIG. 1 is a schematic illustration of an interior space with an audio volume control system according to one aspect disclosed herein;

FIG. 2 is a schematic illustration of a control panel for an audio volume control system according to one aspect disclosed herein;

FIG. 3 is a schematic illustration of an electronic control unit (ECU) according to one aspect disclosed herein;

FIG. 4 is a schematic illustration for a process for reducing a volume of an audio system according to one aspect disclosed herein;

FIG. 5 is a schematic illustration for a process for reducing a volume of an audio system according to one aspect disclosed herein;

FIG. 6 is a schematic illustration for a process for reducing a volume of an audio system according to one aspect disclosed herein;

FIG. 7 is a schematic illustration for a process for reducing a volume of an audio system according to one aspect disclosed herein;

FIG. 8 is a schematic illustration for a process for reducing a volume of an audio system according to one aspect disclosed herein; and

FIG. 9 is a schematic illustration for a process for reducing a volume of an audio system according to one aspect disclosed herein.

### DETAILED DESCRIPTION OF THE INVENTION

An audio volume control system for an audio system that produces and transmits sound an interior space is provided. The system automatically reduces a volume of the sound transmitted into the interior space when an individual within the space is speaking. As such, the audio volume control system has utility for automatically reducing the volume of a radio, CD player, etc. that is playing within a motor vehicle when an individual traveling in the vehicle desires to speak to another individual within the vehicle or speak to someone else using a cell phone.

The audio volume control system includes an interior space within a physical boundary and an audio system with at least one acoustic speaker. The audio system can be any audio system known to those skilled in the art and can include a radio, a CD player, a tape player, an amplifier, and the like. The at least one acoustic speaker is operable to transmit sound into the interior space as is known to those skilled in the art.

A microphone is also included in the audio volume control system and is operable to detect sound waves in the interior space and transmit sound wave signals corresponding to the detected sound waves to an electronic device. It is appreciated that the sound waves can be the result of the sound transmitted by the at least one acoustic speaker and one or more individuals speaking within the interior space.

The audio volume control system also includes an electronic control unit (ECU) in communication with the audio system and the microphone. The ECU can be in direct electrical communication with the audio system and the microphone, and/or in wireless communication therewith. The ECU is configured to instruct the audio system to reduce a volume of sound being transmitted into the interior space when an individual located within the interior space is speaking. In some instances, the ECU can be configured to instruct the audio system to increase the volume of the sound after it is determined that the individual is no longer speaking within the interior space. In this manner, an individual within the interior space can be listening to the audio system and upon starting to speak to another individual in the interior space or beginning to speak on a cell phone, the volume of the audio system is automatically reduced. It is appreciated that the volume of the sound is reduced to such an extent that the individual can speak in a normal tone of voice, i.e. does not have to yell or raise their voice, and thus be able to carry on a normal conversation with another individual within the interior space or via a cell phone. It is also appreciated that when the individual is speaking, he/she is not giving a command to a voice recognition system to reduce the volume of the audio system, i.e. the individual is simply initiating a conversion with another person.

The audio volume control system can include a voice recognition system (VRS) that can recognize a voice of one or more individuals within the interior space and transmit a voice-recognized signal to the ECU. It is appreciated that the VRS can be “trained” to recognize a particular voice, e.g. an operator of a motor vehicle, such that when the individual speaks during the transmission of sound from the audio system, the VRS can distinguish between the voice of the individual and the audio system sound. In this manner, the audio volume control system can determine or distinguish between sound from the audio system and sound from the individual speaking within the interior space.

The audio volume control system can optionally include an occupant detection system (ODS) that is operable to detect when an occupant, i.e. an individual, is in the interior space and transmit an occupant-detected signal to the ECU. In this manner, the audio volume control system can detect when one or more individuals are located within the interior space and thus assist in determining whether or not sound waves detected by the microphone have originated or are caused by an individual that is speaking.

When an ODS is part of the audio volume control system, the ECU can be configured to instruct the audio system to reduce the volume of the sound being transmitted by the audio system into the interior space when both the voice-recognized signal and the occupant-detected signal are received from the VRS and ODS, respectively. The ODS can be any ODS known to those skilled in the art, illustratively including a video camera-based ODS, an ultrasound-based ODS, and/or a weight sensor-based ODS.

The ECU can be configured to receive acoustic signals directly from the audio system with the acoustic signals corresponding to the sound transmitted into the interior space. Stated differently, the audio system can provide a direct feed of acoustic signals that generate sound via the at least one acoustic speaker to the ECU. The ECU can also be configured to subtract the received acoustic signals from the sound wave signals received from the microphone. As such, the ECU can detect if an individual is speaking within the interior space since sound waves originating from the audio system can be removed or subtracted from the sound wave signals transmitted by the microphone. In this manner when an individual is not speaking within the interior space, the resultant signal processed by the ECU corresponds to a relatively quiet interior space. In the alternative, when an individual is speaking in the interior space, the signal processed by the ECU corresponds to the sound of an individual speaking within the interior space.

The audio volume control system can be used in a process for automatically reducing the volume of the audio system when an individual within the interior space is speaking. The audio volume control system detects when a person is speaking within the interior space and the ECU instructs the audio system to reduce a volume of sound being transmitted therein.

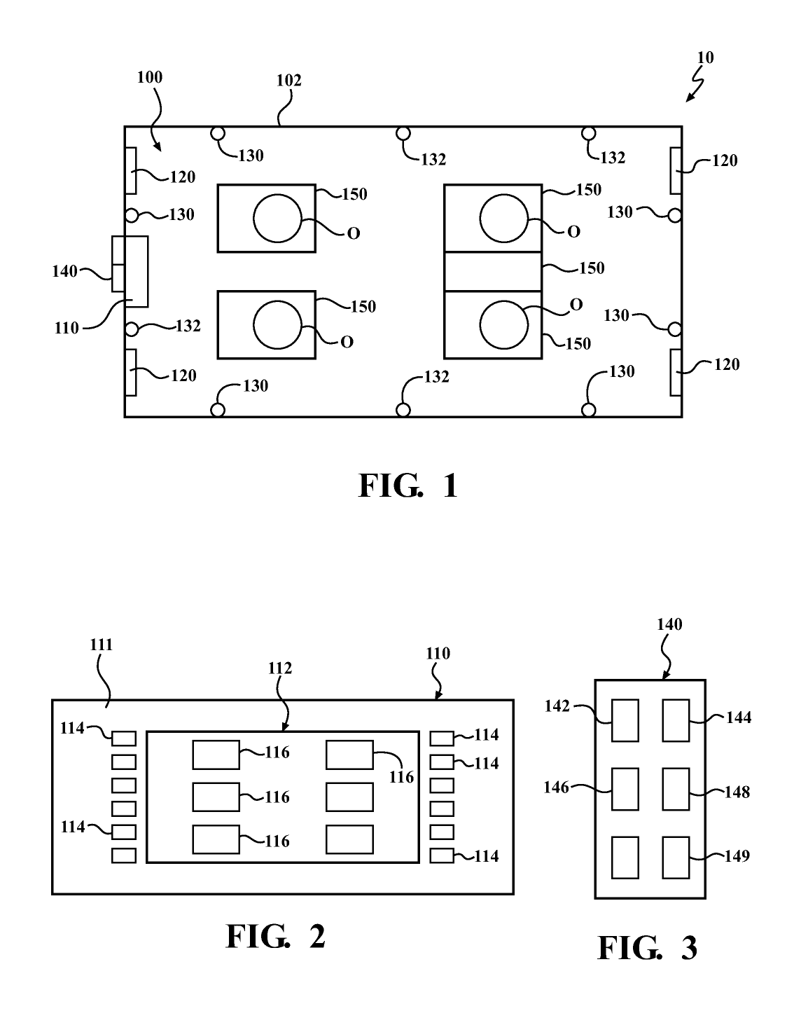

Referring now to FIG. 1, an audio volume control system according to one aspect disclosed herein is shown generally at reference numeral 10. The system includes an interior space 100 within a physical boundary 102. The physical boundary 102 can be one or more walls, windows, and the like. For example and for illustrative purposes, the interior space 100 can be a room within an individual's home, an office within an office building, the interior space of a motor vehicle, and the like.

The system 10 includes an audio system 110 with at least one acoustic speaker 120. As shown in the figure, a plurality of acoustic speakers can be present and located at various locations such that sound in the form of music, news talk radio, etc., is transmitted into the interior space 100. At least one microphone 130 can be included and is operable to detect sound waves in the interior space 100 and also operable to transmit sound wave signals corresponding to the detected sound waves to an electronic device.

The audio system 110 and the microphone 130 are in communication with an ECU 140 and can transmit acoustic signals and sound wave signals, respectively, to the ECU 140. The ECU 140 is configured to instruct the audio system 110 to reduce a volume of sound being transmitted into the interior space 100 when an individual or occupant ‘O’ is detected to be speaking within the interior space 100. More than one occupant O can be located within the interior space 100 and be located at specific locations 150. For example and for illustrative purposes, the locations 150 can be seats within a vehicle interior. As such, the occupants O within the interior space 100 can be seated on the seats 150. In addition, it is appreciated that any one of the occupants O can attempt to communicate or speak with a different occupant O while the audio system 110 is playing music, news, talk radio, etc. in the interior space 100. As such, the audio volume control system 10 affords for the volume of the audio system 110 to be automatically reduced when one of the occupants O begins to speak.

The audio volume control system 10 can include an occupant detection system 132 which is operable to detect if an occupant O is present within the interior space 100 and transmit an occupant-detected signal to the ECU 140. The occupant detection system (ODS) 132 can also detect where the one or more occupants O are located within the interior space 100. As such, the audio volume control system 10 is optionally be energized only when an occupant O is detected within the interior space 100. For example and illustrative purposes, the ODS 132 can be a camera- or video-based ODS that can recognize from a digital image when an occupant ‘O’ is within the interior space 100. In the alternative or in addition to, the ODS 132 can be an ultrasound-based ODS that can determine if one or more occupants are within the interior space 100 via transmitted and received ultrasonic waves. The ODS 132 can also be a weight-sensor based ODS in which the weight of an occupant on a seat, standing pad, etc., can be detected and thus determine if one or more occupants are within the interior space 100.

An illustrative embodiment of a control panel 111 for the audio system 110 is shown in FIG. 2. The control panel 111 includes a display screen 112 and a plurality of control switches 114. The control switches 114 can be activated with a tactile touch and turned, pushed, pulled, etc. For example and for illustrative purposes, the control switches 114 can include a power switch, a volume control switch, a radio station selection switch, a CD track selection switch, a volume control manual override switch and the like. The display screen 112 can also include a touch screen with one or more touch buttons or locations 116 which can also include a power button, a volume control button, a radio station selection button, volume control manual override switch and the like. In this manner, an individual can operate the audio system 110 and listen to music, news, talk radio, and the like, and control the volume thereof transmitted into the interior space 100.

The ECU 140 is illustratively shown in FIG. 3 and can be in the form of a microprocessor that has a central processing unit 142, read only memory (ROM) 144, random access memory (RAM) 146, a software module 148, and an arithmetic logic unit 149. It is appreciated that the various components 142-149 can be in communication with each other via a data bus. It is also a VRS can be included and be in communication with the microphone 130. The ECU 140 is in communication with the audio system 110 and the one or more microphones 130. The ECU 140 can also be in communication with the occupant detection system 132. Finally, the software module 148 can include a voice recognition system that is operable to recognize a voice of an individual or user and transmit a user voice-recognized signal to central processing unit 142. In addition, the VRS can be included within the software module 148 and be trained to recognize a particular voice, e.g. the voice of an owner and/or operator of a vehicle, however, this is not required.

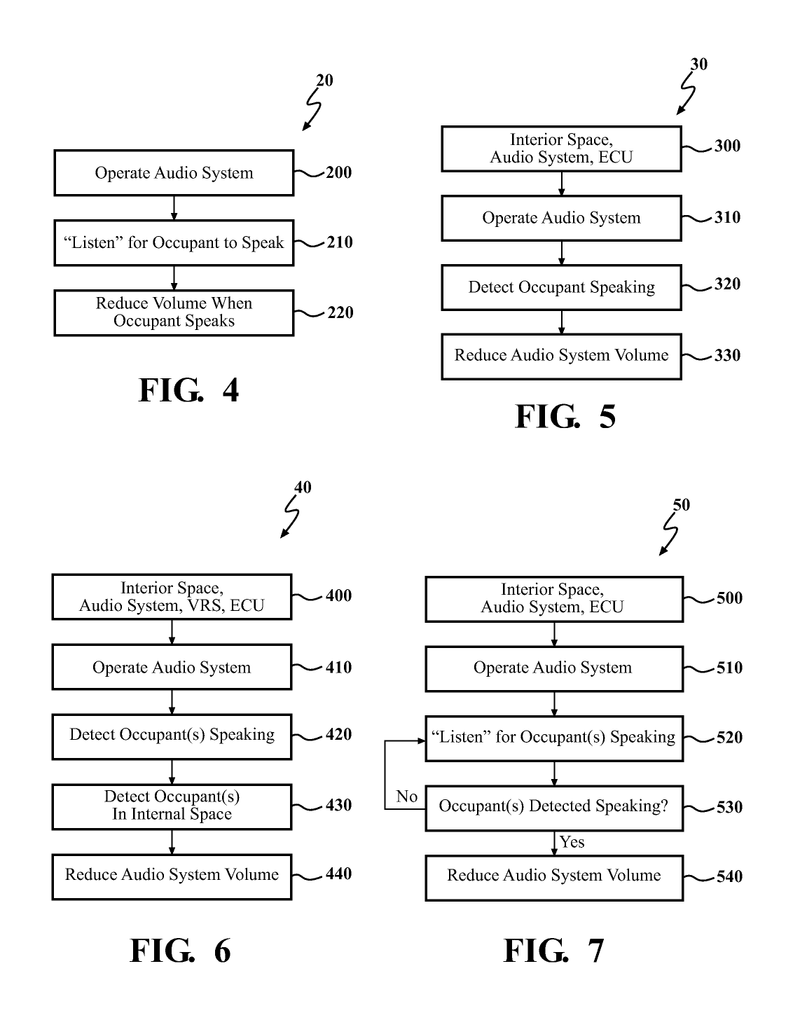

Turning now to FIG. 4, a process according to one aspect disclosed herein is shown generally at reference numeral 20. The process 20 includes operating an audio system at step 200, the audio system transmitting sound into an interior space. The process 20 “listens” for an occupant to speak within the interior space at step 210 and reduces the volume of the audio system when the occupant speaks at step 220. It is appreciated that the terms “listening”, “listen” or “listens” refer to the system being operable to detect when an individual speaks within the interior space.

FIG. 5 provides a process according to another embodiment at reference numeral 30 in which an internal space, audio system, and ECU are provided at step 300. The audio system is operated as is known to those skilled in the art at step 310 and an occupant that is speaking within the internal space is detected at step 320. At step 330 the volume of the audio system is reduced, i.e. the volume of sound being transmitted by the audio system into the interior space is reduced such that the occupant can speak in a “normal” voice. It is appreciated that normal speaking or normal conversation occurs in a range of about 60-65 decibels. In contrast, a person who shouts, yells or is talking very loudly is within a range of 82-88 decibels.

Another process according to one aspect disclosed herein is shown generally at reference numeral 40 in FIG. 6. The process 40 includes providing the internal space, audio system, a VRS, and ECU at step 400. The audio system is operated at step 410 and the VRS detects an occupant speaking within the internal space at step 420. Optionally, an ODS can be included and the ODS can detect an occupant within the internal space at step 430. Furthermore, the volume of the audio system is reduced at step 440 and can be the result of the occupant speaking within the internal space at step 420 and/or the detection of the occupant within the internal space at step 430.

FIG. 7 provides an illustration of another process at reference numeral 50 with the internal space, audio system, and ECU provided at step 500. The audio system is operated at step 510 and the system “listens” for one or more occupants to speak within the internal space at step 520. At step 530, the system determines whether or not one or more occupants are speaking within the internal space. In the event that it is determined that an occupant is not speaking within the internal space, the process returns to step 520. In the alternative, if it is determined that an occupant is speaking, the process proceeds to step 540 and the volume of the audio system is reduced.

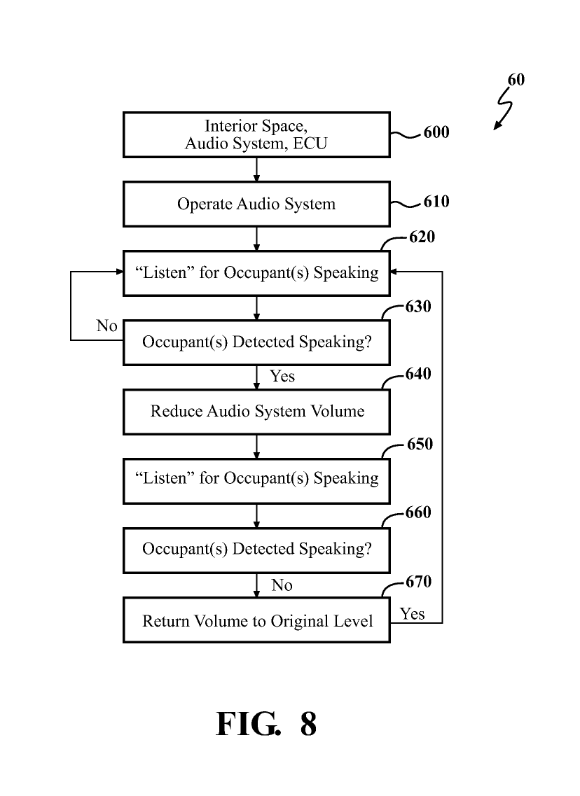

Another process according to one aspect disclosed herein is shown in FIG. 8 at reference numeral 60 where the internal space, audio system, and ECU are provided at step 600. The audio system is operated at step 610 such that sound is transmitted into the interior space. The system listens for one or more occupants to speak at step 620 and determines whether or not one or more occupants are speaking at step 630. In the event that there is no detection of an occupant speaking within the interior space, the process returns to step 620. In the event that an occupant is detected speaking at step 630, the process proceeds to step 640 and the system reduces the volume of the audio system. Thereafter, the system continues to listen for one or more occupants to speak at step 650. When the one or more occupants stop speaking, the process proceeds to step 670 where the volume of the audio system is returned to its original level. Thereafter, the process returns to step 620 and continues until the audio system is turned off or the volume is manually reduced.

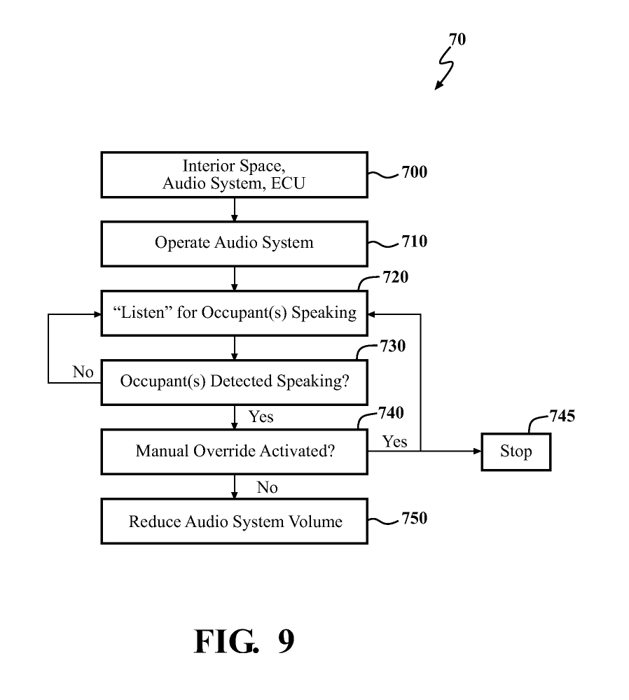

It is appreciated that a volume control manual override in the volume control audio system can be included such that an individual can talk or speak while the audio system continues to operate at a preset volume level. For example and for illustrative purposes, an occupant of a vehicle may want to “sing along” with music playing from the audio system and thus not desire that the volume of the audio system be reduced. Such a process is illustratively shown in FIG. 9 at reference numeral 70. The process includes providing the interior space, audio system, and ECU at step 700 and operating the audio system at step 710. At step 720, the system listens for one or more occupants to speak within the interior space and if no occupant speaking is detected at step 730, the process returns to step 720. In the event that an occupant is detected to be speaking within the interior space, the process proceeds to step 740 in which it is determined if a manual override of the system has been activated. If a manual override has not been activated, the system proceeds to step 750 where the volume of the audio system is reduced. In the alternative, if the manual override has been activated, the process can return to step 720, or in the alternative proceed to “Stop” at step 745 in which a manual reduction of volume by an occupant is required to reduce the volume to the audio system. It is appreciated that the processes illustrated in FIGS. 4-9 can include the audio volume control system having a VRS and/or an ODS as discussed above with the system in FIGS. 1-3.

The above examples, embodiments, etc. are provided for illustrative purposes and are not meant to limit the scope of the instant invention. Changes, modifications, etc. made by those skilled in the art can still fall within the scope of the instant disclosure and thus the scope of the invention is provided by the claims and all equivalents thereof.

We claim:

1. An audio volume control system comprising:
an interior space within a physical boundary;
an audio system with an acoustic speaker, said audio system with said acoustic speaker operable to transmit sound into said interior space;
a microphone operable to detect sound waves in said interior space and transmit sound wave signals corresponding to said detected sound waves; and
an electronic control unit (ECU) in communication with said audio system and said microphone, said ECU instructing said audio system to reduce a volume of sound being transmitted into said interior space when an individual is detected to be speaking within said interior space.

2. The audio volume control system of claim 1, further comprising a voice recognition system (VRS), said VRS operable to recognize a voice of the individual and transmit a voice-recognized signal to said ECU when the voice of the individual is recognized, said ECU instructing said audio system to reduce the volume of sound being transmitted into said interior space when said voice-recognized signal is received from said VRS.

3. The audio volume control system of claim 2, further comprising an occupant detection system (ODS) operable to detect when an occupant is in said interior space and transmit an occupant-detected signal to said ECU when the occupant is detected.

4. The audio volume control system of claim 3, wherein said ECU instructing said audio system to reduce the volume of sound being transmitted into said interior space when said voice-recognized signal is received from said VRS and said occupant-detected signal is received from said ODS.

5. The audio volume control system of claim 4, wherein said ODS is selected from at least one of a camera ODS, an ultrasound ODS and a weight sensor ODS.

6. The audio volume control system of claim 1, wherein said ECU receives acoustic signals corresponding to sound transmitted into said interior space directly from said audio system, said ECU also configured to subtract said received acoustic signals from said sound wave signals received from said microphone.

7. The audio volume control system of claim 6, wherein said ECU instructs said audio system to reduce the volume of sound being transmitted into said interior space after said acoustic signals received directly from said audio system are subtracted from said sound wave signals received from said microphone and the individual is detected to be speaking within said interior space.

8. The audio volume control system of claim 7, further comprising an occupant detection system (ODS) operable to detect when an occupant is in said interior space and transmit an occupant-detected signal to said ECU when the occupant is detected.

9. The audio volume control system of claim 8, wherein said ECU instructs said audio system to reduce the volume of sound being transmitted into said interior space after said acoustic signals received directly from said audio system are subtracted from said sound wave signals received from said microphone and said occupant-detected signal is received from said ODS.

10. The audio volume control system of claim 9, wherein said ODS is selected from at least one of a camera ODS, an ultrasound ODS and a weight sensor ODS.

11. The audio volume control system of claim 1, wherein said interior space is a vehicle interior space.

12. A process for reducing a volume of an audio system when an individual is speaking, the process comprising:
providing an interior space having a physical boundary;
providing an audio system with an acoustic speaker, the audio system transmitting sound in the interior space;
providing a microphone operable to detect sound waves in the interior space and transmit sound wave signals corresponding to the detected sound waves; and
providing an electronic control unit (ECU) in communication with the audio system and the microphone, the ECU configured to receive the transmitted sound wave signals from the microphone and detect when an individual is speaking within the interior space and instruct the audio system to reduce a volume of the sound being transmitted into the interior space;
detecting a person is speaking within the interior space; and
the ECU instructing the audio system to reduce a volume of sound being transmitted into the interior space.

13. The process of claim 12, further including providing a voice recognition system (VRS), the VRS operable to recognize a voice of the person speaking within the interior space and transmit a voice-recognized signal to the ECU when the voice of the person is recognized, the ECU instructing the audio system to reduce the volume of sound being transmitted into said interior space when the voice-recognized signal is received from the VRS.

14. The process of claim 13, further including providing an occupant detection system (ODS) operable to detect when an occupant is in the interior space and transmit an occupant-detected signal to the ECU when the occupant is detected.

15. The process of claim 14, wherein the ECU is configured to instruct the audio system to reduce a volume of sound being transmitted into the interior space when the user voice-recognized signal is received from the VRS and said occupant-detected signal is received from said ODS.

16. The process of claim 12, wherein the ECU is configured to receive acoustic signals corresponding to sound transmitted into the interior space directly from the audio system, the ECU also configured to subtract the received acoustic signals from the sound wave signals received from the microphone.

17. The process of claim 16, wherein the ECU is configured to instruct the audio system to reduce a volume of sound being transmitted into the interior space after the acoustic signals received directly from audio system are subtracted from the sound wave signals received from the microphone.

18. The process of claim 17, further comprising an occupant detection system (ODS) operable to detect when an occupant is in the interior space and transmit an occupant-detected signal to the ECU when the occupant is detected.

19. The process of claim 18, wherein the ECU is configured to instruct the audio system to reduce a volume of sound being transmitted into the interior space after the acoustic signals received directly from audio system are subtracted from the sound wave signals received from the microphone and the occupant-detected signal is received from the ODS.

20. The process of claim 12, wherein the person speaking within the interior space is not speaking a command to reduce the volume of sound being transmitted into the interior space.
